(19) United States
(12) Patent Application Publication
(10) Pub. No.: US 2025/0324851 A1
(43) Pub. Date: Oct. 16, 2025

(54) DISPLAY APPARATUS AND ELECTRONIC APPARATUS INCLUDING THE SAME

(71) Applicant: Samsung Display Co., Ltd., Yongin-Si (KR)

(72) Inventor: Jonghyun Choi, Yongin-si (KR)

(21) Appl. No.: 19/026,374

(22) Filed: Jan. 17, 2025

(30) Foreign Application Priority Data
Apr. 15, 2024 (KR) 10-2024-0050200

(51) Int. Cl. H10K 59/121; H10D 86/40; H10D 86/60; H10K 102/00

(52) U.S. Cl. CPC H10K 59/1216; H10K 59/1213; H10D 86/421; H10D 86/60; H10K 2102/351

(57) ABSTRACT

A display apparatus includes a substrate, a first transistor including a first semiconductor layer disposed on the substrate and a first gate electrode disposed on the first semiconductor layer, wherein the first gate electrode includes a first gate layer and a second gate layer on the first gate layer, a storage capacitor including a first storage capacitor electrode disposed on a same layer as the first semiconductor layer and a second storage capacitor electrode disposed on a same layer as the first gate layer, and a holding capacitor including a first holding capacitor electrode disposed on a same layer as the first semiconductor layer and a second holding capacitor electrode disposed on a same layer as the first gate layer. Each of a thickness of the second storage capacitor electrode and a thickness of the second holding capacitor electrode may be less than a thickness of the first gate electrode.

### CROSS-REFERENCE TO RELATED APPLICATION

This application is based on and claims priority under 35 U.S.C. § 119 to Korean Patent Application No. 10-2024-0050200, filed on Apr. 15, 2024, in the Korean Intellectual Property Office, the disclosure of which is incorporated by reference herein in its entirety.

### BACKGROUND

### 1. Field

The present disclosure relates to a display apparatus capable of displaying high-quality images.

### 2. Description of the Related Art

Recently, display apparatuses have been diversified in their application. In addition, as the thickness of display apparatuses becomes thinner and their weight becomes lighter, the range of the use of display apparatuses have been expanding.

As display apparatuses are used in various ways, various methods for designing the shapes of the display apparatuses have been proposed. In addition, as the display area of display apparatuses increases, various functions are incorporated or linked to the display apparatuses.

In such display apparatuses, thin-film transistors, connection electrodes, and wiring lines may be arranged in each sub-pixel to control the luminance thereof.

### SUMMARY

The present disclosure includes a display apparatus capable of displaying high-quality images. Embodiments set forth herein are examples, and embodiments of the present disclosure are not limited thereto.

Additional aspects will be set forth in the description which follows and will be apparent from the description.

According to an embodiment, a display apparatus includes a substrate, a first transistor including a first semiconductor layer disposed on the substrate and a first gate electrode disposed on the first semiconductor layer, wherein the first gate electrode includes a first gate layer and a second gate layer on the first gate layer, a storage capacitor including a first storage capacitor electrode disposed on a same layer as the first semiconductor layer and a second storage capacitor electrode disposed on a same layer as the first gate layer, and a holding capacitor including a first holding capacitor electrode disposed on a same layer as the first semiconductor layer and a second holding capacitor electrode disposed on a same layer as the first gate layer, wherein each of a thickness of the second storage capacitor electrode and a thickness of the second holding capacitor electrode is less than a thickness of the first gate electrode.

Each of the thickness of the second storage capacitor electrode and the thickness of the second holding capacitor electrode may be less than a thickness of the second gate layer.

Each of the thickness of the second storage capacitor electrode and the thickness of the second holding capacitor electrode may be equal to a thickness of the first gate layer.

A thickness of the first gate layer may be less than a thickness of the second gate layer.

The display apparatus may further include a first insulating layer disposed between the first semiconductor layer and the first gate electrode, and a second insulating layer disposed on the first insulating layer and covering the first gate electrode, wherein the second storage capacitor electrode and the second gate layer may be in contact with the second insulating layer.

The second gate layer may include a conductive material having an etch selectivity with respect to the first gate layer.

The display apparatus may further include a second transistor including a second semiconductor layer disposed on the second storage capacitor electrode and a second gate electrode disposed on the second semiconductor layer.

The holding capacitor may further include a third holding capacitor electrode disposed on the second holding capacitor electrode and electrically connected to the first holding capacitor electrode.

The third holding capacitor electrode may be disposed between the second holding capacitor electrode and the second semiconductor layer.

The holding capacitor may further include a fourth holding capacitor electrode disposed on a same layer as the second semiconductor layer and electrically connected to the second holding capacitor electrode.

The third holding capacitor electrode may be disposed on a same layer as the second semiconductor layer.

The third holding capacitor electrode may be disposed on a same layer as the second gate electrode.

The holding capacitor may further include a fifth holding capacitor electrode disposed under the first semiconductor layer and electrically connected to the second holding capacitor electrode.

The first semiconductor layer may include a silicon semiconductor material, and the second semiconductor layer may include an oxide semiconductor material.

The first semiconductor layer may include an oxide semiconductor material.

According to an embodiment, a display apparatus includes a substrate, a first transistor including a first semiconductor layer disposed on the substrate and a first gate electrode including a first gate layer on the first semiconductor layer and a second gate layer on the first gate layer, and a capacitor including a first capacitor electrode disposed on a same layer as the first semiconductor layer and a second capacitor electrode disposed on a same layer as the first gate layer, wherein a thickness of the second capacitor electrode is less than a thickness of the first gate electrode.

The thickness of the second capacitor electrode may be less than a thickness of the second gate layer.

A thickness of the first gate layer may be less than a thickness of the second gate layer.

The thickness of the second capacitor electrode may be equal to a thickness of the first gate layer.

The display apparatus may further include a first insulating layer disposed between the first semiconductor layer and the first gate electrode, and a second insulating layer disposed on the first insulating layer and covering the first gate electrode, wherein the second capacitor electrode and the second gate layer may be in contact with the second insulating layer.

According to an embodiment, an electronic apparatus includes a display apparatus, wherein the display apparatus may include a substrate, a first transistor including a first semiconductor layer disposed on the substrate and a first gate electrode disposed on the first semiconductor layer, the first gate electrode including a first gate layer and a second gate layer on the first gate layer, a storage capacitor including a first storage capacitor electrode disposed on a same layer as the first semiconductor layer and a second storage capacitor electrode disposed on a same layer as the first gate layer, and a holding capacitor including a first holding capacitor electrode disposed on a same layer as the first semiconductor layer and a second holding capacitor electrode disposed on a same layer as the first gate layer, wherein each of a thickness of the second storage capacitor electrode and a thickness of the second holding capacitor electrode may be less than a thickness of the first gate electrode.

The electronic apparatus may further include a display module, a processor; a power module, and a memory, wherein the display apparatus may include one of the display module, the processor, the power module, or the memory.

### BRIEF DESCRIPTION OF THE DRAWINGS

The above and other aspects, features, and advantages of the present disclosure will become more apparent by reference to the following description taken in conjunction with the accompanying drawings.

FIG. 1 is a schematic plan view showing a portion of a display apparatus according to an embodiment.

FIG. 2 is a schematic side view showing the display apparatus of FIG. 1.

FIG. 3 is an equivalent circuit diagram of a sub-pixel included in the display apparatus of FIG. 1.

FIG. 4 is a schematic cross-sectional view showing a display panel provided in a display apparatus according to an embodiment.

FIG. 5 is a schematic cross-sectional view showing a display panel provided in a display apparatus according to an embodiment.

FIG. 6 is a schematic cross-sectional view showing a display panel provided in a display apparatus according to an embodiment.

FIG. 7 is a schematic cross-sectional view showing a display panel provided in a display apparatus according to an embodiment.

FIG. 8 is a block diagram of an electronic apparatus according to an embodiment.

FIG. 9 is a schematic diagrams of electronic apparatuses according to various embodiments.

### DETAILED DESCRIPTION

Hereinafter, specific embodiments of the present disclosure are explained in detail with reference to the accompanying drawings. Like numerals refer to like elements throughout. In this regard, embodiments of the present disclosure may have different forms and should not be construed as being limited to the descriptions set forth herein. Accordingly, the embodiments are merely described below, by referring to the drawings, to explain aspects of the present description. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

The present disclosure may include various embodiments and modifications, and embodiments thereof will be illustrated in the drawings and will be described herein in detail. The effects and features of the present disclosure and the accompanying methods thereof will become apparent from the following description of the embodiments, taken in conjunction with the accompanying drawings. However, it should be noted that the present disclosure is not limited to the embodiments described below, and may be implemented in various modes.

Hereinafter, embodiments of the disclosure will be described in detail with reference to the accompanying drawings, and in descriptions referring to the drawings, the same reference numerals will be given to the same or corresponding components.

In the following embodiments, it will be understood that when an element, such as a film, a layer, a region, or a board, is referred to as being “formed on” another element, it can be directly or indirectly formed on the other element. That is, for example, an intervening film, layer, region, or board may be present. Sizes of elements in the drawings may be exaggerated or contracted for convenience of description. In other words, because sizes and thicknesses of elements in the drawings are arbitrarily illustrated for convenience of description, the following embodiments are not limited thereto.

In the following embodiments, the x-axis, y-axis, and z-axis are not limited to the three axes in an orthogonal coordinate system and may be interpreted in a broad sense including these. For example, the x-axis, y-axis, and z-axis may be orthogonal to each other, but may also refer to different directions that are not orthogonal to each other.

In the following embodiments, it will be understood that although the terms “first,” “second,” etc. may be used herein to describe various elements, these elements should not be limited by these terms. These elements are only used to distinguish one element from another element.

In the following embodiments, the singular forms “a,” “an,” and “the” are intended to include the plural forms as well, unless the context clearly indicates otherwise.

In the following embodiments, it will be understood that the terms “includes”, “including”, “has”, or “having” used herein specify the presence of stated features or elements, but do not preclude the presence or addition of one or more other features or elements.

In the following embodiments, it will be understood that when a layer, region, or element is referred to as being “connected” to other layer, region, or element, the layer, the region, or the element may be directly connected to, or may be indirectly connected to other layer, other region, or other element with intervening layers, regions, or elements therebetween. For example, when a layer, region, or element is referred to as being “electrically connected to” or “electrically coupled to” another layer, region, or element, it may be directly or indirectly electrically connected or coupled to another layer, region, or element. That is, for example, intervening layers, regions, or elements may be present therebetween.

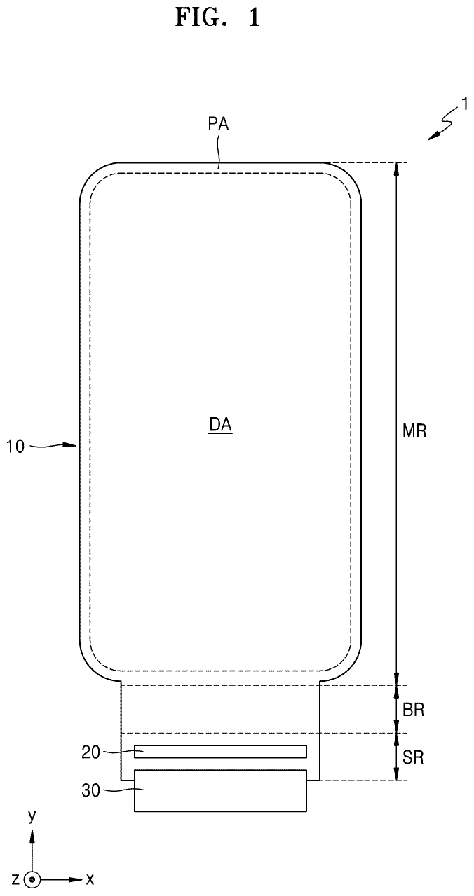

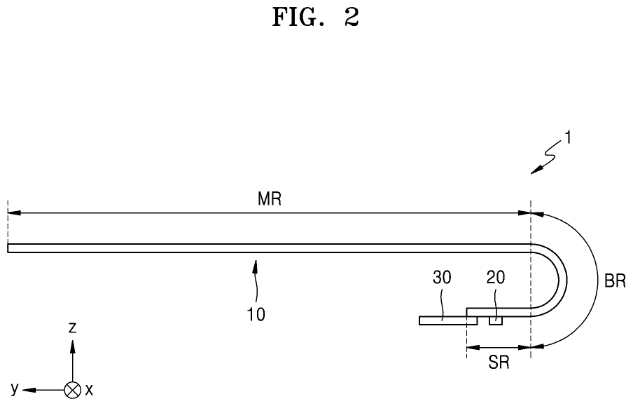

FIG. 1 is a schematic plan view showing a portion of a display apparatus 1 according to an embodiment, and FIG. 2 is a schematic side view showing the display apparatus 1 of FIG. 1. A portion of the display apparatus 1 according to an embodiment of the present disclosure may be bent as shown in FIG. 2. However, for convenience of description, FIG. 1 illustrates the display apparatus 1 as not being bent.

As shown in FIGS. 1 and 2, the display apparatus 1 according to an embodiment of the present disclosure may include a display panel 10. For example, the display apparatus 1 may be one of a variety of products, such as a smartphone, tablet, laptop, television, or billboard.

The display panel 10 includes a display area DA and a peripheral area PA outside the display area DA. The display area DA is a part that displays an image, and a plurality of pixels may be arranged in the display area DA. In FIG. 1, the display area DA has a substantially rectangular shape with round corners. However, the disclosure is not limited thereto, and the shape of the display area DA may be changed in various ways. For example, the display area DA may have various shapes, such as a circular shape, an oval shape, a polygon shape, or a certain shape, when viewed in a direction approximately perpendicular to the display panel 10.

The peripheral area PA may be outside the display area DA. A portion of the peripheral area PA may have the width (in the x-axis direction) less than the width (in the x-axis direction) of the display area DA. Through this structure, at least a portion of the peripheral area PA may be easily bent, as described below.

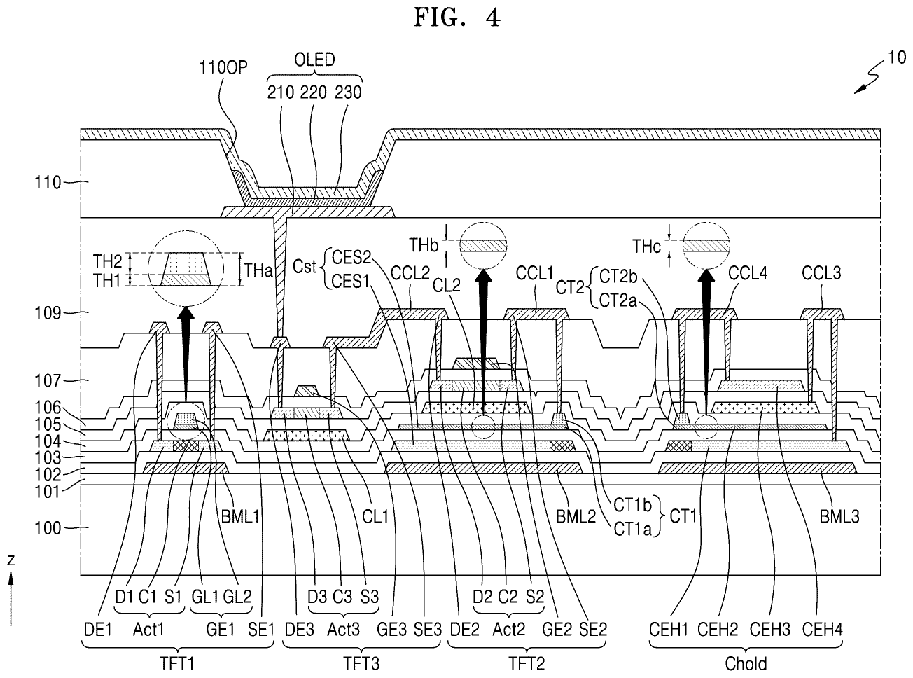

Because the display panel 10 includes a substrate 100 (see FIG. 4), it may be said that the substrate 100 has the display area DA and the peripheral area PA described above. Hereinafter, for convenience of description, the substrate 100 will be described as having the display area DA and the peripheral area PA.

The display panel 10 also may have a main area MR, a bending area BR outside the main area MR, and a sub-area SR on the opposite side of the main area MR with respect to the bending area BR. In the bending area BR, the display panel 10 may be bent as shown in FIG. 2 so that at least a portion of the sub-area SR overlaps the main area MR when viewed in the z-axis direction. However, the present disclosure is not limited to thereto and may also apply to a non-bended display apparatus 1. The sub-area SR may be a non-display area, as described below. By bending the display panel 10 in the bending area BR, a non-display area may not be visible when the display apparatus 1 is viewed from the front (in a-z direction), or if visible, a visible area may be minimized.

A driving chip 20 may be arranged in the sub-region SR of the display panel 10. The driving chip 20 may include an integrated circuit that drives the display panel 10. The integrated circuit may be a data driving integrated circuit that generates data signals, but the disclosure is not limited thereto.

The driving chip 20 may be mounted on the sub-region SR of the display panel 10. The driving chip 20 is mounted on the same surface as a display surface of the display area DA. However, as the display panel 10 is bent in the bending area BR, as described above, the driving chip 20 may be located on the back of the main area MR.

A printed circuit board 30 and the like may be attached to an end of the sub-region SR of the display panel 10. The printed circuit board 30 and the like may be electrically connected to the driving chip 20 through pads (not shown) on the substrate 100.

Hereinafter, the display apparatus 1 according to an embodiment will be described by taking an organic light-emitting display apparatus as an example. However, the display apparatus 1 according to an embodiment is not limited thereto. As an embodiment, the display apparatus 1 may be an inorganic light-emitting display apparatus (or an inorganic electroluminescence (EL) display apparatus) or a quantum dot light-emitting display apparatus. For example, an emission layer of a display element included in the display apparatus 1 may include an organic material or an inorganic material. In addition, the display apparatus 1 may include an emission layer and a quantum dot layer disposed on a path of light emitted from the emission layer.

A plurality of pixels is arranged in the display area DA. Each of the pixels may include a plurality of sub-pixels, and each of the sub-pixels may include a display element, such as an organic light-emitting diode (OLED). The sub-pixel may emit, for example, red, green, blue or white light.

The sub-pixel may be electrically connected to external circuits arranged in the peripheral area PA. A scan driving circuit, an emission control driving circuit, terminals, a first power supply line, a second power supply line, and the like may be arranged in the peripheral area PA. The scan driving circuit may provide a scan signal to the pixel through a scan line. The emission control driving circuit may provide an emission control signal to the pixel through an emission control line. The terminals arranged in the peripheral area PA may not be covered by an insulating layer and may be electrically connected to the printed circuit board 30. Terminals of the printed circuit board 30 may be electrically connected to the terminals of the display panel 10.

The printed circuit board 30 transmits signals or power from a controller (not shown) to the display panel 10. The control signals generated by the controller may be transmitted to each driving circuit through the printed circuit board 30. In addition, the controller may provide a driving power voltage (or driving voltage) ELVDD to the first power supply line and a common power voltage ELVSS to the second power supply line.

The controller may generate a data signal, and the generated data signal may be transmitted to the sub-pixel through the driving chip 20 and a data line.

For reference, a “line” may refer to a “wiring line.” The same applies to an embodiment and its modifications described below.

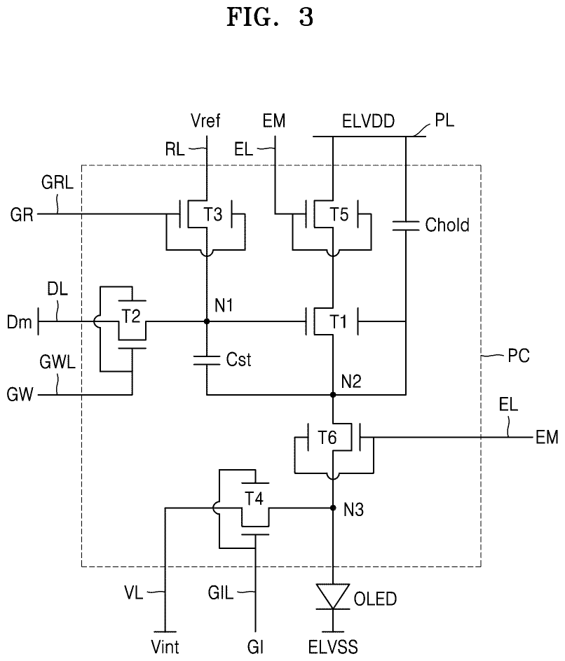

FIG. 3 is an equivalent circuit diagram of a sub-pixel included in the display apparatus 1 of FIG. 1. As shown in FIG. 3, some sub-pixels may include a pixel circuit PC and an organic light-emitting diode OLED electrically connected thereto.

As shown in FIG. 3, the pixel circuit PC may include a plurality of thin-film transistors T1 to T6, a storage capacitor Cst, and a holding capacitor Chold. The plurality of thin-film transistors T1 to T6, the storage capacitor Cst, and the holding capacitor Chold may be connected to signal lines GWL, GRL, GIL, EL, and DL, an initialization voltage line VL, a reference voltage line RL, and a driving voltage line PL.

The plurality of thin-film transistors T1 to T6 may include a driving transistor T1, a switching transistor T2, a reference voltage transistor T3, an initialization transistor T4, an operation control transistor T5, and an emission control transistor T6.

The organic light-emitting diode OLED may include a pixel electrode 210 (see FIG. 4) and an opposite electrode 230 (see FIG. 4). The pixel electrode 210 of the organic light-emitting diode OLED may be electrically connected to the driving transistor T1 via the emission control transistor T6 and receive driving current, and the opposite electrode 230 may receive the common power voltage ELVSS. The organic light-emitting diode OLED may emit light having a brightness corresponding to the driving current.

In an embodiment, the plurality of thin-film transistors T1 to T6 may be n-channel MOSFETs (NMOSs). In an embodiment, when the plurality of thin-film transistors T1 to T6 are NMOSs, each of the plurality of thin-film transistors T1 to T6 may include an oxide semiconductor material. In an embodiment, some of the plurality of thin-film transistors T1 to T6 may be NMOSs and the others may be PMOSs. For example, among the plurality of thin-film transistors T1 to T6, the operation control transistor T5 and the emission control transistor T6 may be PMOSs, and the others may be NMOSs. In another example of the embodiment, among the plurality of thin-film transistors T1 to T6, the operation control transistor T5 and the emission control transistor T6 may be NMOSs, and the others may be PMOSs. In another example of the embodiment, all of the plurality of thin-film transistors T1 to T6 may be PMOSs. In an embodiment, some of the plurality of thin-film transistors T1 to T6 may include amorphous silicon or polysilicon, and the others may include an oxide semiconductor.

The signal lines may include a first scan line GWL configured to transmit a first scan signal GW, a second scan line GRL configured to transmit a second scan signal GR, a third scan line GIL configured to transmit a third scan signal GI, an emission control line EL configured to transmit an emission control signal EM, and a data line DL configured to transmit a data signal Dm.

The initialization voltage line VL may be configured to transmit an initialization voltage Vint that initializes the pixel electrode of the organic light-emitting diode OLED. The reference voltage line RL may be configured to transmit a reference voltage Vref to the gate electrode of the driving transistor T1. The driving voltage line PL may be configured to transmit the driving power voltage ELVDD, which is a driving voltage, to the driving transistor T1.

A driving gate electrode of the driving transistor T1 may be connected to the storage capacitor Cst through a first node N1, a source region of the driving transistor T1 may be connected to the driving voltage line PL via the operation control transistor T5, and a drain region of the driving transistor T1 may be electrically connected to the pixel electrode 210 of the organic light-emitting diode OLED through a second node N2 and the emission control transistor T6. The driving transistor T1 may be configured to receive the data signal Dm in response to a switching operation of the switching transistor T2 and supply a driving current to the organic light-emitting diode OLED. That is, the driving transistor T1 may be configured to control the amount of current flowing to the organic light-emitting diode OLED in response to a voltage applied to the first node N1, which varies depending on the data signal Dm.

A switching gate electrode of the switching transistor T2 may be connected to the first scan line GWL configured to transmit the first scan signal GW, one of the source region and the drain region of the switching transistor T2 may be connected to the data line DL, and the other of the source region and the drain region of the switching transistor T2 may be connected to the driving gate electrode of the driving transistor T1 through the first node N1. The switching transistor T2 may be configured to transmit the data signal Dm from the data line DL to the first node N1 in response to a voltage applied to the first scan line GWL. That is, the switching transistor T2 may be configured to be turned on in response to the first scan signal GW received through the first scan line WL and perform a switching operation to transmit the data signal Dm, transmitted through the data line DL, to the driving transistor T1 through the first node N1.

A reference voltage gate electrode of the reference voltage transistor T3 may be connected to the second scan line GRL configured to transmit the second scan signal GR, one of the source region and the drain region of the reference voltage transistor T3 may be connected to the reference voltage line RL, and the other of the source region and the drain region of the reference voltage transistor T3 may be connected to the driving gate electrode of the driving transistor T1 through the first node N1. The reference voltage transistor T3 may be configured to transmit the reference voltage Vref from the reference voltage line RL to the first node N1 in response to a voltage applied to the second scan line GRL.

An initialization gate electrode of the initialization transistor T4 may be connected to the third scan line GIL, one of the source region and the drain region of the initialization transistor T4 may be connected to the pixel electrode 210 of the organic light-emitting diode OLED through a third node N3, and the other of the source region and the drain region of the initialization transistor T4 may be connected to the initialization voltage line VL to receive the initialization voltage Vint. The initialization transistor T4 may be configured to be turned on in response to the third scan signal GI received through the third scan line GIL and initialize the pixel electrode 210 of the organic light-emitting diode OLED.

An operation control gate electrode of the operation control transistor T5 may be connected to the emission control line EL, one of the source region and the drain region of the operation control transistor T5 may be connected to the driving voltage line PL, and the other may be connected to the source region of the driving transistor T1. The operation control transistor T5 may be configured to be turned on in response to the emission control signal EM received through the emission control line EL, and the driving power voltage ELVDD may be transmitted to the organic light-emitting diode OLED, causing a driving current to flow through the organic light-emitting diode OLED.

An emission control gate electrode of the emission control transistor T6 may be connected to the emission control line EL, one of the source region and the drain region of the emission control transistor T6 may be connected to the drain region of the driving transistor T1 and the storage capacitor Cst through the second node N2, and the other may be connected to the pixel electrode 210 of the organic light-emitting diode OLED through the third node N3. The operation control transistor T5 and the emission control transistor T6 may be simultaneously turned on in response to the emission control signal EM received through the emission control line EL, causing the driving power voltage ELVDD transmitted to the organic light-emitting diode OLED through the driving transistor T1.

A first electrode of the storage capacitor Cst may be connected to the driving gate electrode of the driving transistor T1 through the first node N1, and a second electrode of the storage capacitor Cst may be connected to the drain region of the driving transistor T1 through the second node N2. The storage capacitor Cst may store a charge corresponding to the difference between a driving gate electrode voltage of the driving transistor T1 and the initialization voltage Vint.

A first electrode of the holding capacitor Chold may be connected to the drain region of the driving transistor T1 through the second node N2, and a second electrode of the holding capacitor Chold may be connected to the driving voltage line PL. A compensation voltage to compensate for the threshold voltage of the driving transistor T1 may be stored in the holding capacitor Chold.

A detailed operation of each sub-pixel according to an embodiment is as follows.

During an initialization period, when the third scan signal GI is supplied through the third scan line GIL, the initialization transistor T4 is turned on, and the pixel electrode 210 of the organic light-emitting diode OLED is initialized by the initialization voltage Vint supplied from the initialization voltage line VL. The drain region of the driving transistor T1 and a first capacitor electrode of the holding capacitor Chold, which are electrically connected to the pixel electrode 210 of the organic light-emitting diode OLED through the second node N2 and the emission control transistor T6, are also initialized.

During a compensation period, when the second scan signal GR is supplied through the second scan line GRL, the reference voltage transistor T3 is turned on, and the reference voltage Vref supplied from the reference voltage line RL is transmitted to the driving gate electrode of the driving transistor T1 to compensate for the threshold voltage of the driving transistor T1. A compensation voltage to compensate for the threshold voltage Vth of the driving transistor T1 is stored in the holding capacitor Chold.

During a data programming period, when the first scan signal GW is supplied through the first scan line GWL, the switching transistor T2 is turned on in response to the first scan signal GW. When the switching transistor T2 is turned on, a voltage corresponding to the data signal Dm supplied from the data line DL is applied to the driving gate electrode of the driving transistor T1. The first electrode of the storage capacitor Cst is connected to the driving gate electrode of the driving transistor T1 through the first node N1, and the second electrode of the storage capacitor Cst is connected to the first electrode of the holding capacitor Chold, which stores a compensation voltage that compensates for the threshold voltage of the driving transistor T1. Therefore, the storage capacitor Cst stores a data voltage that is compensated for the threshold voltage of the driving transistor T1.

During an emission period, the operation control transistor T5 and the emission control transistor T6 are turned on by the emission control signal EM supplied from the emission control line EL. Because the first electrode of the storage capacitor Cst is connected to the driving gate electrode of the driving transistor T1 through the first node N1 and the second electrode of the storage capacitor Cst is connected to the drain region of the driving transistor T1 through the second node N2, the data voltage that is compensated for the threshold voltage of the driving transistor T1 is stored in the storage capacitor Cst and a driving current corresponding to the data signal Dm regardless of the threshold voltage Vth of the driving transistor T1 flows through the organic light-emitting diode OLED using the data voltage stored in the storage capacitor Cst.

In an embodiment, at least some of the plurality of thin-film transistors T1 to T6 may include an oxide semiconductor material. The oxide semiconductor material has high carrier mobility and low leakage current, and thus, the voltage drop thereof is not large even though the driving time of the thin-film transistors is long. That is, when the oxide semiconductor material is used, a change in the color of an image due to a voltage drop is not significant even during low-frequency driving, and thus, low-frequency driving is possible. Therefore, by allowing the plurality of thin-film transistors T1 to T6 to include an oxide semiconductor material, the display apparatus 1 may be implemented with reduced power consumption while preventing the occurrence of leakage current.

Since the oxide semiconductor material is sensitive to light, a change in the amount of current may occur due to light from the outside. Therefore, it may be considered to place a metal conductive layer under the oxide semiconductor material to absorb or reflect light from the outside. Accordingly, a transistor including an oxide semiconductor layer may have gate electrodes on the top and bottom of the oxide semiconductor layer, respectively. For example, in the case of the driving transistor T1, a metal layer may be disposed below the oxide semiconductor layer. That is, when viewed in a direction (the z-axis direction) perpendicular to the upper surface of the substrate 100, the metal layer located below the oxide semiconductor layer may overlap the oxide semiconductor layer.

FIG. 4 is a schematic cross-sectional view showing the display panel 10 provided in the display apparatus 1 according to an embodiment.

Referring to FIG. 4, the display panel 10 may include a substrate 100, a plurality of transistors TFT1, TFT2, and TFT3, a storage capacitor Cst, a holding capacitor Chold, and an organic light-emitting diode OLED.

At least some of the plurality of transistors TFT1, TFT2, and TFT3 may be thin-film transistors included in the pixel circuit PC of one sub-pixel depicted in FIG. 3. In an embodiment, the first transistor TFT1 may be a transistor provided in a scan driving circuit or an emission control driving circuit arranged in the peripheral area PA, and the second transistor TFT2 and the third transistor TFT3 may be transistors provided in the pixel circuit PC of a sub-pixel arranged in the display area DA. For example, the second transistor TFT2 may be the driving transistor T1 depicted in FIG. 3, and the third transistor TFT3 may be the emission control transistor T6 depicted in FIG. 3. In an embodiment, each of the first to third transistors TFT1, TFT2, and TFT3 may be a transistor provided in the pixel circuit PC of a sub-pixel arranged in the display area DA. For example, the first transistor TFT1 may be the initialization transistor T4, the second transistor TFT2 may be the driving transistor T1, and the third transistor TFT3 may be the emission control transistor T6 in FIG. 3.

The plurality of transistors TFT1, TFT2, and TFT3, the storage capacitor Cst, and the holding capacitor Chold may be disposed on the substrate 100.

The first transistor TFT1 may include a first semiconductor layer Act1, a first gate electrode GE1 on the first semiconductor layer Act1, a first source electrode SE1, and a first drain electrode DE1. The second transistor TFT2 may include a second semiconductor layer Act2, a second gate electrode GE2 on the second semiconductor layer Act2, a second source electrode SE2, and a second drain electrode DE2. The third transistor TFT3 may include a third semiconductor layer Act3, a third gate electrode GE3, a third source electrode SE3, and a third drain electrode DE3.

The storage capacitor Cst may include a first storage capacitor electrode CES1 and a second storage capacitor electrode CES2 on the first storage capacitor electrode CES1. The first storage capacitor electrode CES1 and the second storage capacitor electrode CES2 may overlap each other.

The holding capacitor Chold may include a first holding capacitor electrode CEH1 and a second holding capacitor electrode CEH2 on the first holding capacitor electrode CEH1. The second holding capacitor electrode CEH2 may overlap the first holding capacitor electrode CEH1. In an embodiment, the holding capacitor Chold may further include a third holding capacitor electrode CEH3 disposed on the second holding capacitor electrode CEH2. The third holding capacitor electrode CEH3 may overlap the second holding capacitor electrode CEH2. In an embodiment, the holding capacitor Chold may further include a fourth holding capacitor electrode CEH4 disposed on the third holding capacitor electrode CEH3. The fourth holding capacitor electrode CEH4 may overlap the third holding capacitor electrode CEH3.

The substrate 100 may be a single layer including glass material. In another example, the substrate 100 may include polymer resin. The substrate 100 including polymer resin may have a structure in which a layer including polymer resin and an inorganic layer are stacked. In an embodiment, the substrate 100 may include a polymer resin, such as polyethersulfone, polyarylate, polyether imide, polyethylene naphthalate, polyethylene terephthalate, polyphenylene sulfide, polyimide, polycarbonate, cellulose triacetate, or cellulose acetate propionate, and may be flexible. The substrate 100 may include glass including SiO₂ as a main component, or may include a resin, such as reinforced plastic, and may have rigid properties.

A first buffer layer 101 including silicon oxide, silicon nitride, or silicon oxynitride may be disposed on the substrate 100. The first buffer layer 101 may planarize the upper surface of the substrate 100.

A lower metal layer including a first lower metal pattern BML1, a second lower metal pattern BML2, and a third lower metal pattern BML3 may be disposed on the first buffer layer 101. In an embodiment, the first lower metal pattern BML1 may overlap the first transistor TFT1, the second lower metal pattern BML2 may overlap the storage capacitor Cst, and the third lower metal pattern BML3 may overlap the holding capacitor Chold.

The first lower metal pattern BML1, the second lower metal pattern BML2, and the third lower metal pattern BML3 may include metal, alloy, or conductive metal oxide. For example, the first lower metal pattern BML1, each of the second lower metal pattern BML2, and the third lower metal pattern BML3 may include silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), or the like. Each of the first lower metal pattern BML1, the second lower metal pattern BML2, and the third lower metal pattern BML3 is shown as a single layer, but is not limited thereto and may have a multi-layer structure.

A second buffer layer 102 may be disposed on the first lower metal pattern BML1, the second lower metal pattern BML2, and the third lower metal pattern BML3. For example, the second buffer layer 102 may cover the first lower metal pattern BML1, the second lower metal pattern BML2 and the third lower metal pattern BML3, and may be disposed on the first buffer layer 101. For example, the second buffer layer 102 may include an insulating material. For example, the second buffer layer 102 may include silicon oxide, silicon nitride, or silicon oxynitride. The second buffer layer 102 may prevent metal atoms, impurities, or the like from diffusing from the substrate 100 to the first semiconductor layer Act1, the first storage capacitor electrode CES1, and the first holding capacitor electrode CEH1, which are disposed on the second buffer layer 102.

The first semiconductor layer Act1, the first storage capacitor electrode CES1, and the first holding capacitor electrode CEH1 may be disposed on the second buffer layer 102. In an embodiment, the first semiconductor layer Act1, the first storage capacitor electrode CES1, and the first holding capacitor electrode CEH1 may be disposed on the same layer. In the present disclosure, being disposed on the same layer may mean that layers disposed on the same layer are formed substantially at the same time (e.g., layers formed by the same process operation). The first semiconductor layer Act1, the first storage capacitor electrode CES1, and the first holding capacitor electrode CEH1 may be formed through the same process and may include the same material. For example, each of the first semiconductor layer Act1, the first storage capacitor electrode CES1, and the first holding capacitor electrode CEH1 may include a silicon semiconductor material. For example, each of the first semiconductor layer Act1, the first storage capacitor electrode CES1, and the first holding capacitor electrode CEH1 may include amorphous silicon or polysilicon. Specifically, each of the first semiconductor layer Act1, the first storage capacitor electrode CES1, and the first holding capacitor electrode CEH1 may include polysilicon crystallized at a low temperature. If necessary, ions may be implanted into at least a portion of each of the first semiconductor layer Act1, the first storage capacitor electrode CES1, and the first holding capacitor electrode CEH1. For example, a first source region S1 and a first drain region D1 may be formed by implanting ions into a portion of the first semiconductor layer Act1. A first channel region C1 may be a region between the first source region S1 and the first drain region D1 and may overlap the first gate electrode GE1 that will be described below. Also, the first storage capacitor electrode CES1 or the first holding capacitor electrode CEH1 may include a portion having ions implanted into it.

A first gate insulating layer 103 may be disposed on the first semiconductor layer Act1, the first storage capacitor electrode CES1, and the first holding capacitor electrode CEH1. For example, the first gate insulating layer 103 may cover the first semiconductor layer Act1, the first storage capacitor electrode CES1, and the first holding capacitor electrode CEH1, and be disposed on the second buffer layer 102. For example, the first gate insulating layer 103 may be disposed between the first semiconductor layer Act1 and the first gate electrode GE1. For example, the first gate insulating layer 103 may be disposed between the first storage capacitor electrode CES1 and the second storage capacitor electrode CES2. For example, the first gate insulating layer 103 may be disposed between the first holding capacitor electrode CEH1 and the second holding capacitor electrode CEH2.

For example, the first gate insulating layer 103 may include an insulating material. For example, the first gate insulating layer 103 may include an inorganic insulating layer, such as silicon oxide, silicon nitride, silicon oxynitride, or aluminum oxide. The first gate insulating layer 103 may have a multi-layer structure including the inorganic insulating layer.

The first gate electrode GE1, the second storage capacitor electrode CES2, and the second holding capacitor electrode CEH2 may be disposed on the first gate insulating layer 103.

The first gate electrode GE1 may include a first gate layer GL1 and a second gate layer GL2 on the first gate layer GL1. The first gate layer GL1 and the second gate layer GL2 may include conductive materials having different etch rates. That is, the second gate layer GL2 may include a conductive material having an etch selectivity with respect to the first gate layer GL1. For example, each of the first gate layer GL1 and the second gate layer GL2 may include a conductive material, such as silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), gold (Au), cobalt (Co), iron (Fe), indium tin oxide (ITO), or indium zinc oxide (IZO). For example, in order for the first gate layer GL1 and the second gate layer GL2 to have different etch rates, the first gate layer GL1 may include titanium (Ti) and the second gate layer GL2 may include molybdenum (Mo). In another example, the first gate layer GL1 may include indium tin oxide (ITO), and the second gate layer GL2 may include molybdenum (Mo). For example, the first gate layer GL1 and the second gate layer GL2 may include different materials selected from among conductive materials, such as silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), gold (Au), cobalt (Co), iron (Fe), indium tin oxide (ITO), and indium zinc oxide (IZO).

A thickness TH1 of the first gate layer GL1 may be less than a thickness TH2 of the second gate layer GL2. In an embodiment, a thickness THb of the second storage capacitor electrode CES2 and a thickness THc of the second holding capacitor electrode CEH2 may be substantially equal to the thickness TH1 of the first gate layer GL1. The thickness THb of the second storage capacitor electrode CES2 may be less than a thickness THa of the first gate electrode GE1. The thickness THb of the second storage capacitor electrode CES2 may be less than the thickness TH2 of the second gate layer GL2. The thickness THc of the second holding capacitor electrode CEH2 may be less than the thickness THa of the first gate electrode GE1. The thickness THc of the second holding capacitor electrode CEH2 may be less than the thickness TH2 of the second gate layer GL2.

In an embodiment, the thickness THb of the second storage capacitor electrode CES2 and the thickness THc of the second holding capacitor electrode CEH2 may be small enough to allow ions to pass therethrough by a subsequent doping process. For example, the thickness THb of the second storage capacitor electrode CES2 and the thickness THc of the second holding capacitor electrode CEH2 may each range from about 200 Å to about 1,500 Å. For example, the thickness THb of the second storage capacitor electrode CES2 and the thickness THc of the second holding capacitor electrode CEH2 may each range from about 200 Å to about 1000 Å.

Because the thickness THb of the second storage capacitor electrode CES2 and the thickness THc of the second holding capacitor electrode CEH2 are small, ions may be implanted, by a doping process subsequently performed, into each of the first storage capacitor electrode CES1 disposed below the second storage capacitor electrode CES2 and the first holding capacitor electrode CEH1 disposed below the second holding capacitor electrode CEH2, and thus, the first storage capacitor electrode CES1 and the first holding capacitor electrode CEH1 may be electrically conductive. That is, the semiconductor patterns formed in the same process as the first semiconductor layer Ac1 and disposed on the same layer may have conductivity. Using the conductivity, the first storage capacitor electrode CES1 and the first holding capacitor electrode CEH1 may form the storage capacitor Cst and the holding capacitor Chold.

As the storage capacitor Cst is provided with the first storage capacitor electrode CES1 including a semiconductor material and the second storage capacitor electrode CES2 overlapping the first storage capacitor electrode CES1, the capacity of the storage capacitor Cst may be increased without increasing the area in a plan view of the storage capacitor Cst. Likewise, as the holding capacitor Chold is provided with the first holding capacitor electrode CEH1 including a semiconductor material and the second holding capacitor electrode CEH2 overlapping the first holding capacitor electrode CEH1, the capacity of the holding capacitor Chold may be increased without increasing the area in a plan view of the holding capacitor Chold. Accordingly, the resolution of the display panel 10 may increase, allowing high-quality images to be displayed.

The first gate layer GL1 of the first gate electrode GE1, the second storage capacitor electrode CES2, and the second holding capacitor electrode CEH2 may be disposed on the same layer. The first gate layer GL1 of the first gate electrode GE1, the second storage capacitor electrode CES2, and the second holding capacitor electrode CEH2 may be formed through the same process and may include the same material. For example, when the first gate layer GL1 includes titanium (Ti), the second storage capacitor electrode CES2 and the second holding capacitor electrode CEH2 may also include titanium (Ti).

In an embodiment, the first gate electrode GE1, the second storage capacitor electrode CES2, and the second holding capacitor electrode CEH2 may be formed to have different thicknesses through a halftone mask process. For example, a photoresist pattern forming the first gate electrode GE1 may have a thickness greater than the thickness of a photoresist pattern forming the second storage capacitor electrode CES2 and the second holding capacitor electrode CEH2. However, a method of forming the first gate electrode GE1, the second storage capacitor electrode CES2, and the second holding capacitor electrode CEH2 is not limited thereto. In an embodiment, by forming the first gate electrode GE1, a preliminary second storage capacitor electrode, and a preliminary second holding capacitor electrode, each of which has two conductive layers (e.g., a lower conductive layer and an upper conductive layer) having different etch rates, and etching the upper conductive layer of the preliminary second storage capacitor electrode and the upper conductive layer of the preliminary second holding capacitor electrode, the second storage capacitor electrode CES2 and the second holding capacitor electrode CEH2, each having a thickness less than the thickness of the first gate electrode GE1, may be formed.

In an embodiment, the first gate electrode GE1 may overlap the first lower metal pattern BML1. The first lower metal pattern BML1 may function as a gate electrode of the first transistor TFT1 together with the first gate electrode GE1. That is, the first gate electrode GE1 may be an upper gate electrode of the first transistor TFT1, and the first lower metal pattern BML1 may be a lower gate electrode of the first transistor TFT1. In addition to functioning as a gate electrode, the first lower metal pattern BML1 may function as a lower protection metal that protects parts overlapping the first lower metal pattern BML1. Likewise, the second lower metal pattern BML2 may protect the storage capacitor Cst overlapping the second lower metal pattern BML2, and the third lower metal pattern BML3 may function as a lower protection metal that protects the holding capacitor Chold overlapping the third lower metal pattern BML3.

A second gate insulating layer 104 may be disposed on the first gate electrode GE1, the second storage capacitor electrode CES2, and the second holding capacitor electrode CEH2. For example, the second gate insulating layer 104 may cover the first gate electrode GE1, the second storage capacitor electrode CES2, and the second holding capacitor electrode CEH2, and be disposed on the first gate insulating layer 103. For example, the second gate insulating layer 104 may be disposed between the second storage capacitor electrode CES2 and the second conductive layer CL2. For example, the second gate insulating layer 104 may be disposed between the second holding capacitor electrode CEH2 and the third holding capacitor electrode CEH3. For example, the second gate insulating layer 104 may be in contact with the second gate layer GL2 of the first gate electrode GE1, the second storage capacitor electrode CES2, and the second holding capacitor electrode CEH2.

For example, the second gate insulating layer 104 may include an insulating material. For example, the second gate insulating layer 104 may include an inorganic insulating layer, such as silicon oxide, silicon nitride, silicon oxynitride, or aluminum oxide. The second gate insulating layer 104 may have a multi-layer structure including the inorganic insulating layer.

A first conductive layer CL1, a second conductive layer CL2, and the third holding capacitor electrode CEH3 may be disposed on the second gate insulating layer 104. In an embodiment, the third holding capacitor electrode CEH3 may be disposed between the second holding capacitor electrode CEH2 and the fourth holding capacitor electrode CEH4. The first conductive layer CL1 may overlap the third transistor TFT3, and the second conductive layer CL2 may overlap the second transistor TFT2.

The first conductive layer CL1, the second conductive layer CL2, and the third holding capacitor electrode CEH3 may include metal, alloy, or conductive metal oxide. For example, the first conductive layer CL1, each of the second conductive layer CL2, and the third holding capacitor electrode CEH3 may include silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), or the like. Each of the first conductive layer CL1, the second conductive layer CL2, and the third holding capacitor electrode CEH3 is shown as a single layer, but is not limited thereto and may have a multi-layer structure.

A first interlayer insulating layer 105 may be disposed on the first conductive layer CL1, the second conductive layer CL2, and the third holding capacitor electrode CEH3. For example, the first interlayer insulating layer 105 may cover the first conductive layer CL1, the second conductive layer CL2, and the third holding capacitor electrode CEH3, and may be disposed on the second gate insulating layer 104. The first interlayer insulating layer 105 may be disposed between the third holding capacitor electrode CEH3 and the fourth holding capacitor electrode CEH4. For example, the first interlayer insulating layer 105 may include an insulating material. For example, the first interlayer insulating layer 105 may include an inorganic insulating layer, such as silicon oxide, silicon nitride, silicon oxynitride, or aluminum oxide. The first interlayer insulating layer 105 may have a multi-layer structure including the inorganic insulating layer.

The second semiconductor layer Act2, the third semiconductor layer Act3, and the fourth holding capacitor electrode CEH4 may be disposed on the first interlayer insulating layer 105. For example, the second semiconductor layer Act2 may be disposed on the second storage capacitor electrode CES2. In an embodiment, the second semiconductor layer Act2, the third semiconductor layer Act3, and the fourth holding capacitor electrode CEH4 may be disposed on the same layer. The second semiconductor layer Act2, the third semiconductor layer Act3, and the fourth holding capacitor electrode CEH4 may be formed through the same process and may include the same material. For example, each of the second semiconductor layer Act2, the third semiconductor layer Act3, and the fourth holding capacitor electrode CEH4 may include an oxide semiconductor material. For example, each of the second semiconductor layer Act2, the third semiconductor layer Act3, and the fourth holding capacitor electrode CEH4 may include ITGZO.

For example, the second source region S2 and the second drain region D2 of the second semiconductor layer Act2 may be formed by reducing, i.e., deoxidizing, an oxide semiconductor. For example, the second source region S2 and the second drain region D2 of the second semiconductor layer Act2 may include an oxide semiconductor and may further include at least one of fluorine (F), hydrogen (H), and sulfur(S). At the boundary between the second source region S2 and a second channel region C2 in the second semiconductor layer Act2 and the boundary between the second drain region D2 and the second channel region C2 in the second semiconductor layer Act2, there may be a gradient region in which the concentration of at least one of fluorine (F), hydrogen (H), and sulfur(S) gradually changes. The second source region S2 and the second drain region D2 of the second semiconductor layer Act2 may be formed by making an oxide semiconductor conductive through a method such as plasma treatment. For example, the second source region S2 and the second drain region D2 may be formed by plasma-treating the oxide semiconductor in a hydrogen gas atmosphere to diffuse hydrogen into the oxide semiconductor and make the oxide semiconductor conductive. The second channel region C2 may be a region between the second source region S2 and the second drain region D2 and may overlap the second gate electrode GE2 that will be described below.

Likewise, a third source region S3 and a third drain region D3 of the third semiconductor layer Act3 may be formed by reducing, i.e., deoxidizing, an oxide semiconductor. For example, the third source region S3 and the third drain region D3 of the third semiconductor layer Act3 may include an oxide semiconductor and may further include at least one of fluorine (F), hydrogen (H), and sulfur(S). At the boundary between the third source region S3 and a third channel region C3 in the third semiconductor layer Act3 and the boundary between the third drain region D3 and the third channel region C3 in the third semiconductor layer Act3, there may be a gradient region in which the concentration of at least one of fluorine (F), hydrogen (H), and sulfur(S) gradually changes. The third source region S3 and the third drain region D3 of the third semiconductor layer Act3 may be formed by making an oxide semiconductor conductive through a method such as plasma treatment. For example, the third source region S3 and the third drain region D3 may be formed by plasma-treating the oxide semiconductor in a hydrogen gas atmosphere to diffuse hydrogen into the oxide semiconductor and make the oxide semiconductor conductive. The third channel region C3 may be a region between the third source region S3 and the third drain region D3 and may overlap the third gate electrode GE3 that will be described below.

Likewise, the fourth holding capacitor electrode CEH4 may be formed by reducing, i.e., deoxidizing, an oxide semiconductor. The fourth holding capacitor electrode CEH4 may include an oxide semiconductor and may further include at least one of fluorine (F), hydrogen (H), and sulfur(S). For example, the fourth holding capacitor electrode CEH4 may be formed by plasma-treating the oxide semiconductor in a hydrogen gas atmosphere to diffuse hydrogen into the oxide semiconductor and make the oxide semiconductor conductive.

The third gate insulating layer 106 may be disposed on the second semiconductor layer Act2, the third semiconductor layer Act3, and the fourth holding capacitor electrode CEH4. For example, the third gate insulating layer 106 may cover the second semiconductor layer Act2, the third semiconductor layer Act3, and the fourth holding capacitor electrode CEH4, and be disposed on the first interlayer insulating layer 105. For example, the third gate insulating layer 106 may be disposed between the second semiconductor layer Act2 and the second gate electrode GE2. For example, the third gate insulating layer 106 may be disposed between the third semiconductor layer Act3 and the third gate electrode GE3.

For example, the third gate insulating layer 106 may include an insulating material. For example, the third gate insulating layer 106 may include an inorganic insulating layer, such as silicon oxide, silicon nitride, silicon oxynitride, or aluminum oxide. The third gate insulating layer 106 may have a multi-layer structure including the inorganic insulating layer.

The second gate electrode GE2 and the third gate electrode GE3 may be disposed on the third gate insulating layer 106.

The second gate electrode GE2 and the third gate electrode GE3 may be disposed on the same layer. The second gate electrode GE2 and the third gate electrode GE3 may be formed through the same process and may include the same material. For example, each of the second gate electrode GE2 and the third gate electrode GE3 may include a conductive material, such as silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO).

In an embodiment, the third gate electrode GE3 may overlap the first conductive layer CL1. The first conductive layer CL1 may function as a gate electrode of the third transistor TFT3 together with the third gate electrode GE3. That is, the third gate electrode GE3 may be an upper gate electrode of the third transistor TFT3, and the first conductive layer CL1 may be a lower gate electrode of the third transistor TFT3. In addition to functioning as a gate electrode, the first conductive layer CL1 may function as a lower protection metal that protects parts overlapping the first conductive layer CL1.

In an embodiment, the second gate electrode GE2 may overlap the second conductive layer CL2. The second conductive layer CL2 may function as a gate electrode of the second transistor TFT2 together with the second gate electrode GE2. That is, the second gate electrode GE2 may be an upper gate electrode of the second transistor TFT2, and the second conductive layer CL2 may be a lower gate electrode of the second transistor TFT2. In addition to functioning as a gate electrode, the second conductive layer CL2 may function as a lower protection metal that protects parts overlapping the second conductive layer CL2.

The second interlayer insulating layer 107 may be disposed on the second gate electrode GE2 and the third gate electrode GE3. For example, the second interlayer insulating layer 107 may cover the second gate electrode GE2 and the third gate electrode GE3, and be disposed on the third gate insulating layer 106. For example, the second interlayer insulating layer 107 may include an insulating material. For example, the second interlayer insulating layer 107 may include an inorganic insulating layer, such as silicon oxide, silicon nitride, silicon oxynitride, or aluminum oxide. The second interlayer insulating layer 107 may have a multi-layer structure including the inorganic insulating layer.

The first source and the first drain electrodes SE1 and DE1, the second source and the second drain electrodes SE2 and DE2, the third source and the third drain electrodes SE3 and DE3, and first to fourth connection conductive layers CCL1, CCL2, CCL3, and CCL4 may be disposed on the second interlayer insulating layer 107.

The first source electrode SE1 and the first drain electrodes DE1 may be electrically connected to the first source region S1 and the first drain region D1 of the first semiconductor layer Act1, respectively. The second source electrode SE2 and the second drain electrode DE2 may be electrically connected to the second source region S2 and the second drain region D2 of the second semiconductor layer Act2, respectively. The third source electrode SE3 and the third drain electrode DE3 may be electrically connected to the third source region S3 and the third drain region D3 of the third semiconductor layer Act3, respectively.

In an embodiment, the second source region S2 of the second transistor TFT2 and the second storage capacitor electrode CES2 of the storage capacitor Cst may be electrically connected to each other by the first connection conductive layer CCL1. For example, the second storage capacitor electrode CES2 may be electrically connected to the first connection conductive layer CCL1 through a first contact portion CT1. That is, the second storage capacitor electrode CES2 may be electrically connected to the second transistor TFT2 through the first contact portion CT1 and the first connection conductive layer CCL1. The first contact portion CT1 may include a first contact layer CT1a formed integrally with the second storage capacitor electrode CES2, and a second contact layer CT1b on the first contact layer CT1a. The second contact layer CT1b may be formed through the same process as the second gate layer GL2 of the first gate electrode GE1 and may include the same material as the second gate layer GL2. In addition, the second contact layer CT1b may have substantially the same thickness as the second gate layer GL2.

In an embodiment, the second drain region D2 of the second transistor TFT2 and the third source region S3 of the third transistor TFT3 may be electrically connected to each other by the second connection conductive layer CCL2.

In an embodiment, the third holding capacitor electrode CEH3 may be electrically connected to the first holding capacitor electrode CEH1 by the third connection conductive layer CCL3. As the second holding capacitor electrode CEH2 is disposed between the first holding capacitor electrode CEH1 and the third holding capacitor electrode CEH3, and the first holding capacitor electrode CEH1 and the third holding capacitor electrode CEH3 are electrically connected to each other, a capacitor may be formed by the first holding capacitor electrode CEH1, the second holding capacitor electrode CEH2, and the first gate insulating layer 103, and a capacitor may be formed by the second holding capacitor electrode CEH2, the third holding capacitor electrode CEH3, and the second gate insulating layer 104. Accordingly, the capacity of the holding capacitor Chold may be increased without increasing the area of the holding capacitor Chold.

In an embodiment, the fourth holding capacitor electrode CEH4 may be electrically connected to the second holding capacitor electrode CEH2 by the fourth connection conductive layer CCL4. As the third holding capacitor electrode CEH3 is disposed between the second holding capacitor electrode CEH2 and the fourth holding capacitor electrode CEH4, and the second holding capacitor electrode CEH2 and the fourth holding capacitor electrode CEH4 are electrically connected to each other, a capacitor may be formed by the second holding capacitor electrode CEH2, the third holding capacitor electrode CEH3, and the second gate insulating layer 104, and a capacitor may be formed by the third holding capacitor electrode CEH3, the fourth holding capacitor electrode CEH4, and the first interlayer insulating layer 105. Accordingly, the capacity of the holding capacitor Chold may be increased without increasing the area of the holding capacitor Chold.

For example, the second holding capacitor electrode CEH2 may be electrically connected to the fourth connection conductive layer CCL4 by a second contact portion CT2. That is, the second holding capacitor electrode CEH2 may be electrically connected to the fourth holding capacitor electrode CEH4 by the second contact portion CT2 and the fourth connection conductive layer CCL4. The second contact portion CT2 may include a third contact layer CT2a formed integrally with the second holding capacitor electrode CEH2, and a fourth contact layer CT2b on the third contact layer CT2a. The fourth contact layer CT2b may be formed through the same process as the second gate layer GL2 of the first gate electrode GE1 and may include the same material as the second gate layer GL2. In addition, the fourth contact layer CT2b may have substantially the same thickness as the second gate layer GL2.

The first source and the first drain electrodes SE1 and DE1, the second source and the second drain electrodes SE2 and DE2, the third source and the third drain electrodes SE3 and DE3, and the first to fourth connection conductive layers CCL1, CCL2, CCL3, and CCL4 may include metal, alloy, conductive metal oxide, transparent conductive material, or the like. For example, the first source and the first drain electrodes SE1 and DE1, the second source and the second drain electrodes SE2 and DE2, the third source and the third drain electrodes SE3 and DE3, and the first to fourth connection conductive layers CCL1, CCL2, CCL3, and CCL4 may each include a conductive material, such as silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO).

Although FIG. 4 illustrates that the second transistor TFT2 overlap the storage capacitor Cst, the disclosure is not limited thereto. In an embodiment, the second transistor TFT2 and the storage capacitor Cst may not overlap each other.

A via insulation layer 109 may be disposed on the first source and the first drain electrodes SE1 and DE1, the second source and the second drain electrodes SE2 and DE2, the third source and the third drain electrodes SE3 and DE3, and the first to fourth connection conductive layers CCL1, CCL2, CCL3, and CCL4. For example, the via insulation layer 109 may cover the first source and the first drain electrodes SE1 and DE1, the second source and the second drain electrodes SE2 and DE2, the third source and the third drain electrodes SE3 and DE3, and the first to fourth connection conductive layers CCL1, CCL2, CCL3, and CCL4, and be located on the second interlayer insulating layer 107. The via insulation layer 109 may include an organic insulating material. For example, the via insulation layer 109 may include photoresist, benzocyclobutene (BCB), polyimide, hexamethyldisiloxane (HMDSO), polymethylmethacrylate (PMMA), polystyrene, a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, or the like.

An organic light-emitting diode OLED may be disposed on the via insulation layer 109. The organic light-emitting diode OLED may include a pixel electrode 210, an intermediate layer 220 including an emission layer, and an opposite electrode 230. For example, the organic light-emitting diode OLED may be electrically connected to the third transistor TFT3.

The pixel electrode 210 may be a (semi-) light-transmitting electrode or a reflective electrode. For example, the pixel electrode 210 may include a reflective layer including Ag, Mg, Al, Pt, Pd, Au, Ni, Nd, Ir, Cr, or a compound thereof, and a transparent or translucent electrode layer disposed on the reflective layer. The transparent or translucent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). For example, the pixel electrode 210 may have a three-layer structure including ITO/Ag/ITO layers.

A pixel-defining layer 110 may be disposed on the via insulation layer 109. The pixel-defining layer 110 may prevent an arc or the like from occurring at the edge of the pixel electrode 210 by increasing the distance between the edge of the pixel electrode 210 and the opposite electrode 230 over the pixel electrode 210. The pixel-defining layer 110 may include one or more organic insulating materials selected from the group consisting of polyimide, polyamide, acrylic resin, benzocyclobutene, and phenol resin and may be formed by a method, such as spin coating.

At least a portion of the intermediate layer 220 of the organic light-emitting diode OLED may be disposed within an opening 110OP formed by the pixel-defining layer 110. The emission area of the organic light-emitting diode OLED may be defined by the opening 110OP of the pixel-defining layer 110.

The intermediate layer 220 may include an emission layer. The emission layer may include an organic material containing a fluorescent or phosphorescent material that emits red, green, blue, or white light. The emission layer may include a low molecular weight organic material or a high molecular weight organic material, and below and above the emission layer 320, a functional layer, such as a hole transport layer (HTL), a hole injection layer (HIL), an electron transport layer (ETL), and an electron injection layer (EIL), may be selectively further disposed.

The emission layer may have a patterned shape corresponding to each of the pixel electrodes 210. Each of the layers except for the emission layer included in the intermediate layer 220 may be modified in various ways, such as may be integrally formed across the plurality of pixel electrodes 210.

The opposite electrode 230 may be a light-transmitting electrode or a reflective electrode. For example, the opposite electrode 230 may be a transparent or translucent electrode and may include a metal thin film having a low work function and including Li, Ca, LiF, Al, Ag, Mg, or a compound thereof. In addition, the opposite electrode 230 may further include a transparent conductive oxide (TCO) layer including ITO, IZO, ZnO, or In₂O₃ disposed on the metal thin film. The opposite electrode 230 may be formed integrally over the entire display area DA (see FIG. 1) and disposed on the intermediate layer 220 and the pixel-defining layer 110.

The embodiments described below are modified embodiments of FIG. 4, and repeated descriptions indicated by the same reference numerals will be omitted or simplified and the description will focus on changed parts.

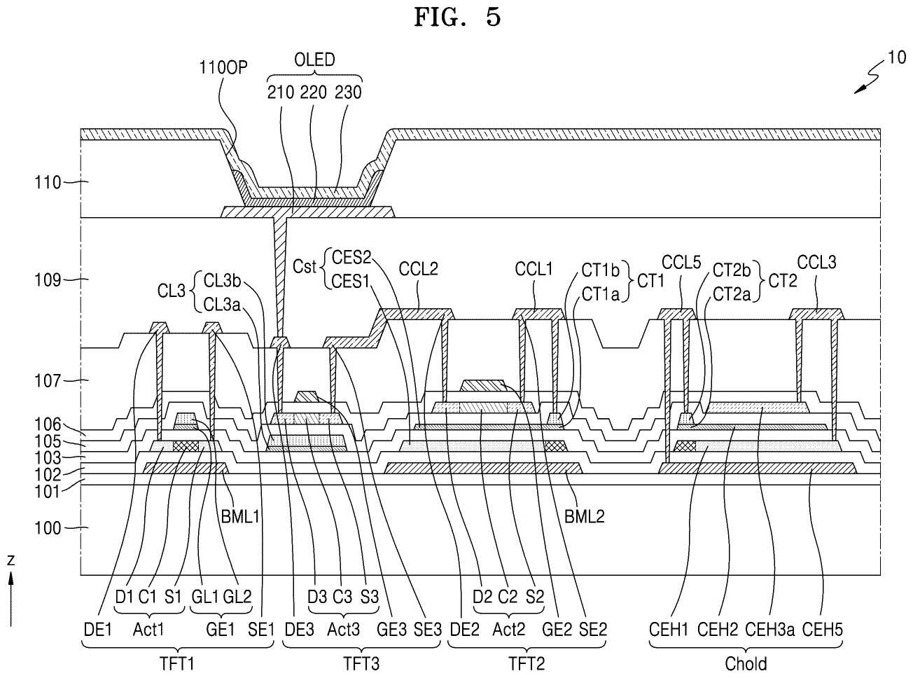

FIG. 5 is a schematic cross-sectional view showing the display panel 10 provided in the display apparatus 1 according to an embodiment. In the embodiment of FIG. 5, a conductive layer (e.g., the first conductive layer CL1 and the second conductive layer CL2) between the second storage capacitor electrode CES2 and the second semiconductor layer Act2, and the second gate insulating layer 104 depicted in FIG. 4 may be omitted.

Referring to FIG. 5, the holding capacitor Chold may further include a fifth holding capacitor electrode CEH5 disposed below the first holding capacitor electrode CEH1. For example, the fifth holding capacitor electrode CEH5 may be disposed on a layer, e.g., the first buffer layer 101, disposed under the first semiconductor layer Act1. The fifth holding capacitor electrode CEH5 may be disposed on the same layer as the first lower metal pattern BML1 and the second lower metal pattern BML2. The fifth holding capacitor electrode CEH5 may be formed in the same process as the first lower metal pattern BML1 and the second lower metal pattern BML2, and include the same material as the first lower metal pattern BML1 and the second lower metal pattern BML2.

The second buffer layer 102 may be disposed on the first lower metal pattern BML1, the second lower metal pattern BML2, and the fifth holding capacitor electrode CEH5. For example, the second buffer layer 102 may cover the first lower metal pattern BML1, the second lower metal pattern BML2, and the fifth holding capacitor electrode CEH5, and may be disposed on the first buffer layer 101.

The first interlayer insulating layer 105 may be disposed on the first gate electrode GE1, the third conductive layer CL3, the second storage capacitor electrode CES2, and the second holding capacitor electrode CEH2. For example, the first interlayer insulating layer 105 may cover the first gate electrode GE1, the third conductive layer CL3, the second storage capacitor electrode CES2, and the second holding capacitor electrode CEH2, and may be disposed on the first gate insulating layer 103. For example, the first interlayer insulating layer 105 may be disposed between the third conductive layer CL3 and the third semiconductor layer Act3. For example, the first interlayer insulating layer 105 may be disposed between the second storage capacitor electrode CES2 and the second semiconductor layer Act2. For example, the first interlayer insulating layer 105 may be disposed between the second holding capacitor electrode CEH2 and a third holding capacitor electrode CEH3a. For example, the first interlayer insulating layer 105 may be in contact with the second gate layer GL2 of the first gate electrode GE1, an upper conductive layer CL3b of the third conductive layer CL3, the second storage capacitor electrode CES2, and the second holding capacitor electrode CEH2.

The third conductive layer CL3 may be formed through the same process as the first gate electrode GE1. The third conductive layer CL3 may include a lower conductive layer CL3a and the upper conductive layer CL3b. The lower conductive layer CL3a and the upper conductive layer CL3b of the third conductive layer CL3 may include conductive materials having different etch rates. That is, the upper conductive layer CL3b of the third conductive layer CL3 may include a conductive material having an etch selectivity with respect to the lower conductive layer CL3a of the third conductive layer CL3.

The lower conductive layer CL3a of the third conductive layer CL3, the first gate layer GL1 of the first gate electrode GE1, the second storage capacitor electrode CES2, and the second holding capacitor electrode CEH2 may be disposed on the same layer. The lower conductive layer CL3a of the third conductive layer CL3, the first gate layer GL1 of the first gate electrode GE1, the second storage capacitor electrode CES2, and the second holding capacitor electrode CEH2 may be formed through the same process and include the same material. For example, when the first gate layer GL1 includes titanium (Ti), the lower conductive layer CL3a of the third conductive layer CL3 may also include titanium (Ti).

The upper conductive layer CL3b of the third conductive layer CL3 and the second gate layer GL2 of the first gate electrode GE1 may be disposed on the same layer. The upper conductive layer CL3b of the third conductive layer CL3 and the second gate layer GL2 of the first gate electrode GE1 may be formed through the same process and include the same material. For example, when the second gate layer GL2 includes molybdenum (Mo), the upper conductive layer CL3b of the third conductive layer CL3 may also include molybdenum (Mo).

The thickness of the lower conductive layer CL3a of the third conductive layer CL3 may be less than the thickness of the upper conductive layer CL3b of the third conductive layer CL3. In an embodiment, the thickness of the lower conductive layer CL3a of the third conductive layer CL3 may be substantially equal to the thickness of the first gate layer GL1 of the first gate electrode GE1. In an embodiment, the thickness of the upper conductive layer CL3b of the third conductive layer CL3 may be substantially equal to the thickness of the second gate layer GL2 of the first gate electrode GE1.

In an embodiment, the third gate electrode GE3 may overlap the third conductive layer CL3. The third conductive layer CL3 may function as a gate electrode of the third transistor TFT3 together with the third gate electrode GE3. That is, the third gate electrode GE3 may be an upper gate electrode of the third transistor TFT3, and the third conductive layer CL3 may be a lower gate electrode of the third transistor TFT3. In addition to functioning as a gate electrode, the third conductive layer CL3 may function as a lower protection metal that protects parts overlapping the third conductive layer CL3.

In an embodiment, the third holding capacitor electrode CEH3a disposed on the second holding capacitor electrode CEH2 may be disposed between the second holding capacitor electrode CEH2 and the second gate electrode GE2. For example, the third holding capacitor electrode CEH3a may be disposed on the same layer as the second semiconductor layer Act2 and the third semiconductor layer Act3. The second semiconductor layer Act2, the third semiconductor layer Act3, and the third holding capacitor electrode CEH3a may be formed through the same process and include the same material. For example, each of the second semiconductor layer Act2, the third semiconductor layer Act3, and the third holding capacitor electrode CEH3a may include an oxide semiconductor material. For example, each of the second semiconductor layer Act2, the third semiconductor layer Act3, and the third holding capacitor electrode CEH3a may include ITGZO. The second semiconductor layer Act2, the third semiconductor layer Act3, and the third holding capacitor electrode CEH3a may be disposed on the first interlayer insulating layer 105.

In an embodiment, the third holding capacitor electrode CEH3a may be electrically connected to the first holding capacitor electrode CEH1 by the third connection conductive layer CCL3. As the second holding capacitor electrode CEH2 is disposed between the first holding capacitor electrode CEH1 and the third holding capacitor electrode CEH3a, and the first holding capacitor electrode CEH1 and the third holding capacitor electrode CEH3a are electrically connected to each other, a capacitor may be formed by the first holding capacitor electrode CEH1, the second holding capacitor electrode CEH2, and the first gate insulating layer 103, and a capacitor may be formed by the second holding capacitor electrode CEH2, the third holding capacitor electrode CEH3a, and the first interlayer insulating layer 105. Accordingly, the capacity of the holding capacitor Chold may be increased without increasing the area of the holding capacitor Chold.

In an embodiment, the fifth holding capacitor electrode CEH5 may be electrically connected to the second holding capacitor electrode CEH2 by the fifth connection conductive layer CCL5. As the first holding capacitor electrode CEH1 is disposed between the second holding capacitor electrode CEH2 and the fifth holding capacitor electrode CEH5, and the second holding capacitor electrode CEH2 and the fifth holding capacitor electrode CEH5 are electrically connected to each other, a capacitor may be formed by the first holding capacitor electrode CEH1, the fifth holding capacitor electrode CEH5, and the second buffer layer 102 disposed between the first holding capacitor electrode CEH1 and the fifth holding capacitor electrode CEH5, and a capacitor may be formed by the first holding capacitor electrode CEH1, the second holding capacitor electrode CEH2, and the first gate insulating layer 103. Accordingly, the capacity of the holding capacitor Chold may be increased without increasing the area of the holding capacitor Chold.

For example, the second holding capacitor electrode CEH2 may be electrically connected to the fifth connection conductive layer CCL5 by the second contact portion CT2. That is, the second holding capacitor electrode CEH2 may be electrically connected to the fifth holding capacitor electrode CEH5 by the second contact portion CT2 and the fifth connection conductive layer CCL5.

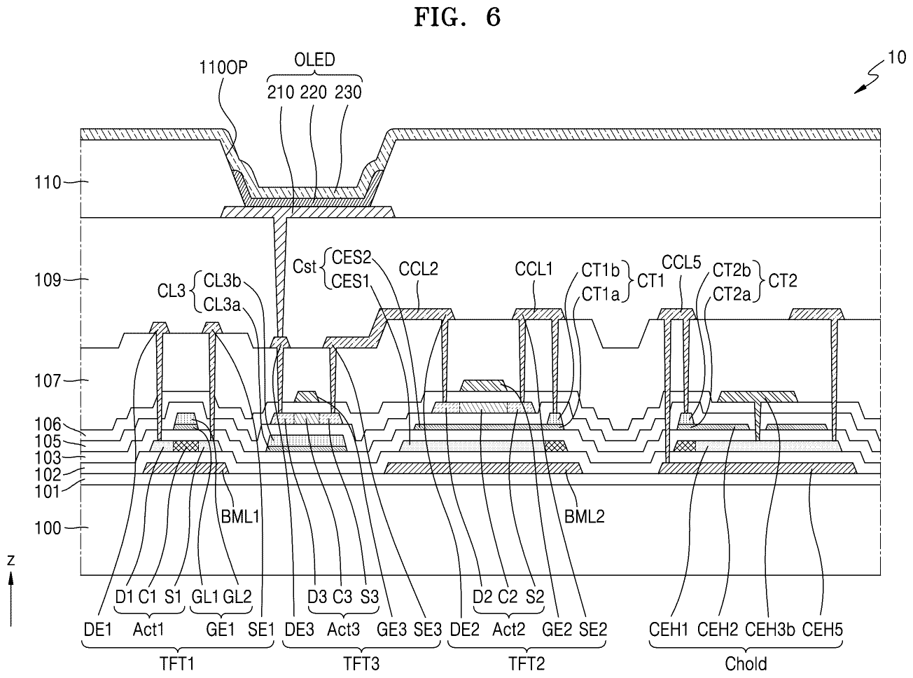

FIG. 6 is a schematic cross-sectional view showing the display panel 10 provided in the display apparatus 1 according to an embodiment. The embodiment shown in FIG. 6 is a modified embodiment depicted in FIG. 5, and redundant description will be omitted.

Referring to FIG. 6, a third holding capacitor electrode CEH3b disposed on the second holding capacitor electrode CEH2 may be disposed on the same layer as the second gate electrode GE2 and the third gate electrode GE3. For example, the third holding capacitor electrode CEH3b may be disposed on the second semiconductor layer Act2 and the third semiconductor layer Act3. The second gate electrode GE2, the third gate electrode GE3, and the third holding capacitor electrode CEH3b may be disposed on the third gate insulating layer 106.

For example, the second gate electrode GE2, the third gate electrode GE3, and the third holding capacitor electrode CEH3b may be formed through the same process and include the same material. For example, each of the second gate electrode GE2, the third gate electrode GE3, and the third holding capacitor electrode CEH3b may include a conductive material, such as silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO).

In an embodiment, the third holding capacitor electrode CEH3b may be electrically connected to the first holding capacitor electrode CEH1. For example, the third holding capacitor electrode CEH3b may be electrically connected to the first holding capacitor electrode CEH1 through a first contact hole passing through insulating layers (e.g., the first gate insulating layer 103, the first interlayer insulating layer 105, and the third gate insulating layer 106) between the first holding capacitor electrode CEH1 and the third holding capacitor electrode CEH3b. For example, the second holding capacitor electrode CEH2 may have an opening, and the first contact hole is formed in a portion corresponding to the opening of the second holding capacitor electrode CEH2. In an embodiment, the third holding capacitor electrode CEH3b and the first holding capacitor electrode CEH1 may be connected to each other by a connection conductive layer on the second interlayer insulating layer 107.

As the second holding capacitor electrode CEH2 is disposed between the first holding capacitor electrode CEH1 and the third holding capacitor electrode CEH3b, and the first holding capacitor electrode CEH1 and the third holding capacitor electrode CEH3b are electrically connected to each other, a capacitor may be formed by the first holding capacitor electrode CEH1, the second holding capacitor electrode CEH2, and the first gate insulating layer 103, and a capacitor may be formed by the second holding capacitor electrode CEH2, the third holding capacitor electrode CEH3a, the first interlayer insulating layer 105, and the third gate insulating layer 106. Accordingly, the capacity of the holding capacitor Chold may be increased without increasing the area of the holding capacitor Chold.

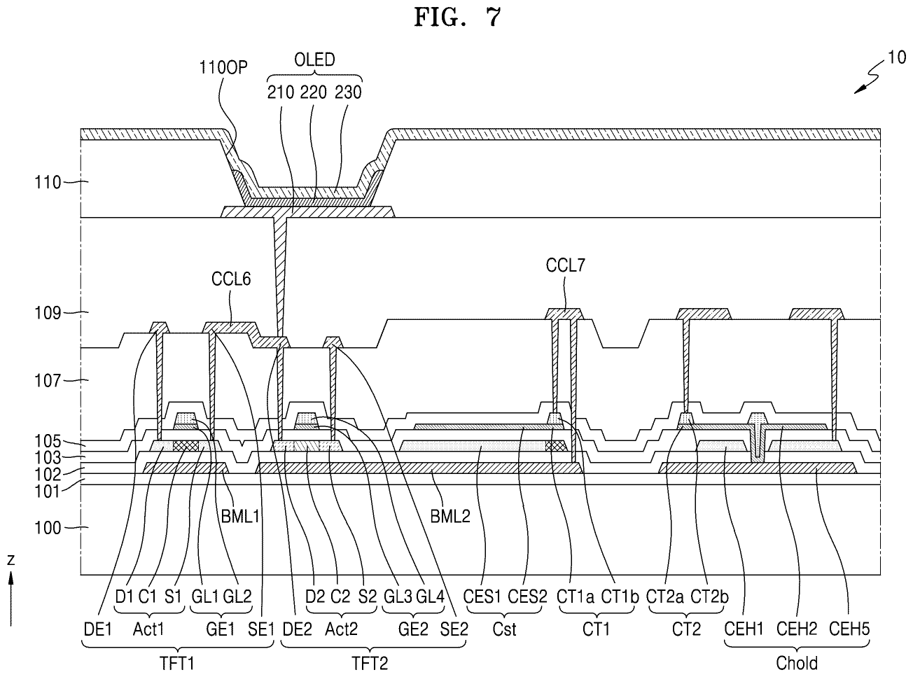

FIG. 7 is a schematic cross-sectional view showing the display panel 10 provided in the display apparatus 1 according to an embodiment.

Referring to FIG. 7, the display panel 10 may include a substrate 100, a plurality of transistors including first and second transistors TFT1 and TFT2, a storage capacitor Cst, a holding capacitor Chold, and an organic light-emitting diode OLED. The first and second transistors TFT1 and TFT2 may be thin-film transistors included in the pixel circuit PC of one sub-pixel described with reference to FIG. 3. Each of the first and second transistors TFT1 and TFT2 may include a semiconductor layer including an oxide semiconductor material. For example, the first transistor TFT1 may be the emission control transistor T6 depicted in FIG. 3, and the second transistor TFT2 may be the driving transistor T1 depicted in FIG. 3.

A lower metal layer including the first lower metal pattern BML1, the second lower metal pattern BML2, and the fifth holding capacitor electrode CEH5 may be disposed on the first buffer layer 101.

The second buffer layer 102 may be disposed on the first lower metal pattern BML1, the second lower metal pattern BML2, and the fifth holding capacitor electrode CEH5. For example, the second buffer layer 102 may cover the first lower metal pattern BML1, the second lower metal pattern BML2, and the fifth holding capacitor electrode CEH5, and may be disposed on the first buffer layer 101.

The first semiconductor layer Act1, the second semiconductor layer Act2, the first storage capacitor electrode CES1, and the first holding capacitor electrode CEH1 may be disposed on the second buffer layer 102. In an embodiment, the first semiconductor layer Act1, the second semiconductor layer Act2, the first storage capacitor electrode CES1, and the first holding capacitor electrode CEH1 may be disposed on the same layer. The first semiconductor layer Act1, the second semiconductor layer Act2, the first storage capacitor electrode CES1, and the first holding capacitor electrode CEH1 may be formed through the same process and include the same material. For example, each of the first semiconductor layer Act1, the second semiconductor layer Act2, the first storage capacitor electrode CES1, and the first holding capacitor electrode CEH1 may include an oxide semiconductor material.

For example, the first source region S1 and the first drain region D1 of the first semiconductor layer Act1 may be formed by reducing, i.e., deoxidizing, an oxide semiconductor. For example, the first source region S1 and the first drain region D1 of the first semiconductor layer Act1 may include an oxide semiconductor and may further include at least one of fluorine (F), hydrogen (H), and sulfur(S). At the boundary between the first source region S1 and the first channel region C1 in the first semiconductor layer Act1 and the boundary between the first drain region D1 and the first channel region C1 in the first semiconductor layer Act1, there may be a gradient region in which the concentration of at least one of fluorine (F), hydrogen (H), and sulfur(S) gradually changes. The first source region S1 and the first drain region D1 of the first semiconductor layer Act1 may be formed by making an oxide semiconductor conductive through a method such as plasma treatment. For example, the first source region S1 and the first drain region D1 may be formed by plasma-treating the oxide semiconductor in a hydrogen gas atmosphere to diffuse hydrogen into the oxide semiconductor and make the oxide semiconductor conductive. The first channel region C1 may be a region between the first source region S1 and the first drain region D1. Likewise, the second source region S2 and the second drain region D2 of the second semiconductor layer Act2 may be formed by reducing, i.e., deoxidizing, an oxide semiconductor. Likewise, the first holding capacitor electrode CEH1 and the first storage capacitor electrode CES1 may be formed by reducing, i.e., deoxidizing, an oxide semiconductor.

The first gate insulating layer 103 may be disposed on the first semiconductor layer Act1, the second semiconductor layer Act2, the first storage capacitor electrode CES1, and the first holding capacitor electrode CEH1. For example, the first gate insulating layer 103 may cover the first semiconductor layer Act1, the second semiconductor layer Act2, the first storage capacitor electrode CES1, and the first holding capacitor electrode CEH1, and may be disposed on the buffer layer 102. For example, the first gate insulating layer 103 may be disposed between the first semiconductor layer Act1 and the first gate electrode GE1, and between the second semiconductor layer Act2 and the second gate electrode GE2. For example, the first gate insulating layer 103 may be disposed between the first storage capacitor electrode CES1 and the second storage capacitor electrode CES2. For example, the first gate insulating layer 103 may be disposed between the first holding capacitor electrode CEH1 and the second holding capacitor electrode CEH2.

The first gate electrode GE1, the second gate electrode GE2, the second storage capacitor electrode CES2, and the second holding capacitor electrode CEH2 may be disposed on the first gate insulating layer 103.

The second gate electrode GE2 may include a third gate layer GL3 and a fourth gate layer GL4 on the third gate layer GL3. The third gate layer GL3 of the second gate electrode GE2, the first gate layer GL1 of the first gate electrode GE1, the second storage capacitor electrode CES2, and the second holding capacitor electrode CEH2 may be formed by the same process and include the same material. The fourth gate layer GL4 of the second gate electrode GE2 may be formed through the same process as the second gate layer GL2 of the first gate electrode GE1 and include the same material as the second gate layer GL2. For example, the third gate layer GL3 and the fourth gate layer GL4 may include conductive materials having different etch rates. That is, the third gate layer GL3 may include a conductive material having an etch selectivity with respect to the fourth gate layer GL4.

The thickness of the third gate layer GL3 may be less than the thickness of the fourth gate layer GL4. In an embodiment, the thickness of the third gate layer GL3 may be substantially equal to the thickness of the first gate layer GL1. The thickness of the fourth gate layer GL4 may be substantially equal to the thickness of the second gate layer GL2. The thickness of the second storage capacitor electrode CES2 may be less than the thickness of the first gate electrode GE1 and the thickness of the second gate electrode GE2. The thickness of the second storage capacitor electrode CES2 may be less than the thickness of the second gate layer GL2 and the thickness of the fourth gate layer GL4. The thickness of the second holding capacitor electrode CEH2 may be less than the thickness of the first gate electrode GE1 and the thickness of the second gate electrode GE2. The thickness of the second holding capacitor electrode CEH2 may be less than the thickness of the second gate layer GL2 and the thickness of the fourth gate layer GL4.

The first interlayer insulating layer 105 may be disposed on the first gate electrode GE1, the second gate electrode GE2, the second storage capacitor electrode CES2, and the second holding capacitor electrode CEH2. For example, the first interlayer insulating layer 105 may cover the first gate electrode GE1, the second gate electrode GE2, the second storage capacitor electrode CES2, and the second holding capacitor electrode CEH2, and be disposed on the gate insulating layer 103. For example, the first interlayer insulating layer 105 may be in contact with the second gate layer GL2 of the first gate electrode GE1, the fourth gate layer GL4 of the second gate electrode GE2, the second storage capacitor electrode CES2, and the second holding capacitor electrode CEH2.

A second interlayer insulating layer 107 may be disposed on the first interlayer insulating layer 105. First source and first drain electrodes SE1 and DE1, second source and second drain electrodes SE2 and DE2, a sixth connection conductive layer CCL6, and a seventh connection conductive layer CCL7 may be disposed on the second interlayer insulating layer 107.

In an embodiment, the first source region S1 of the first transistor TFT1 and the second drain region D2 of the second transistor TFT2 may be electrically connected to each other by the sixth connection conductive layer CCL6.

Although FIG. 7 illustrates that the second semiconductor layer Act2 of the second transistor TFT2 and the first storage capacitor electrode CES1 of the storage capacitor Cst are not connected to each other, the present disclosure is not limited thereto. For example, the second semiconductor layer Act2 of the second transistor TFT2 and the first storage capacitor electrode CES1 of the storage capacitor Cst may be electrically connected to each other.

The second storage capacitor electrode CES2 of the storage capacitor Cst may be electrically connected to the second lower metal pattern BML2 by the seventh connection conductive layer CCL7. That is, the second lower metal pattern BML2 may function as a storage capacitor electrode of the storage capacitor Cst. For example, the storage capacitor Cst may include a capacitor formed by the second lower metal pattern BML2, the first storage capacitor electrode CES1, and the second buffer layer 102, and a capacitor formed by the first storage capacitor electrode CES1, the second storage capacitor electrode CES2, and the first gate insulating layer 103.

The holding capacitor Chold may include a first holding capacitor electrode CEH1 and a second holding capacitor electrode CEH2 on the first holding capacitor electrode CEH1. The holding capacitor Chold may further include a fifth holding capacitor electrode CEH5 below the first holding capacitor electrode CEH1.

In an embodiment, the second holding capacitor electrode CEH2 may be electrically connected to the fifth holding capacitor electrode CEH5. For example, the second holding capacitor electrode CEH2 may be electrically connected to the fifth holding capacitor electrode CEH5 through a second contact hole passing through insulating layers (e.g., the second buffer layer 102 and the first gate insulating layer 103) between the second holding capacitor electrode CEH2 and the fifth holding capacitor electrode CEH5. For example, the first holding capacitor electrode CEH1 may have an opening, and the second contact hole is formed in a portion corresponding to the opening of the first holding capacitor electrode. In an embodiment, the second holding capacitor electrode CEH2 and the fifth holding capacitor electrode CEH5 may be connected to each other by a connection conductive layer on the second interlayer insulating layer 107.

As the first holding capacitor electrode CEH1 is disposed between the fifth holding capacitor electrode CEH5 and the second holding capacitor electrode CEH2, and the second holding capacitor electrode CEH2 and the fifth holding capacitor electrode CEH5 are electrically connected to each other, a capacitor may be formed by the fifth holding capacitor electrode CEH5, the first holding capacitor electrode CEH1, and the second buffer layer 102, and a capacitor may be formed by the first holding capacitor electrode CEH1, the second holding capacitor electrode CEH2, the first interlayer insulating layer 105, and the first gate insulating layer 103. Accordingly, the capacity of the holding capacitor Chold may be increased without increasing the area of the holding capacitor Chold.

The display apparatus according to the embodiment may be applied to various electronic apparatuses. An electronic apparatus according to an embodiment of the present disclosure may include the display apparatus (e.g., the display apparatus of FIG. 1) described above, and may further include modules or apparatuses having additional functions in addition to the display apparatus.

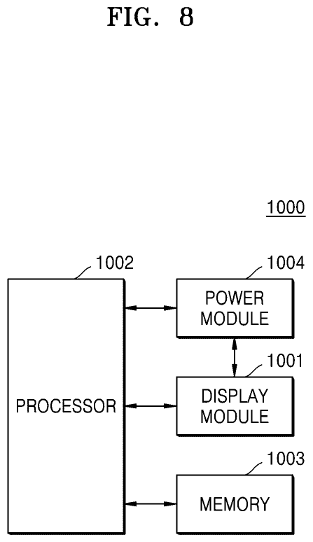

FIG. 8 is a block diagram of an electronic apparatus according to an embodiment.

Referring to FIG. 8, an electronic apparatus 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic apparatus 1000.

At least one of the components of the electronic apparatus 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic apparatus 1000 except for the display apparatus.

In an embodiment, the display module 1001 included in the display apparatus may drive based on the image data signal and the input control signal received from the processor 1002.

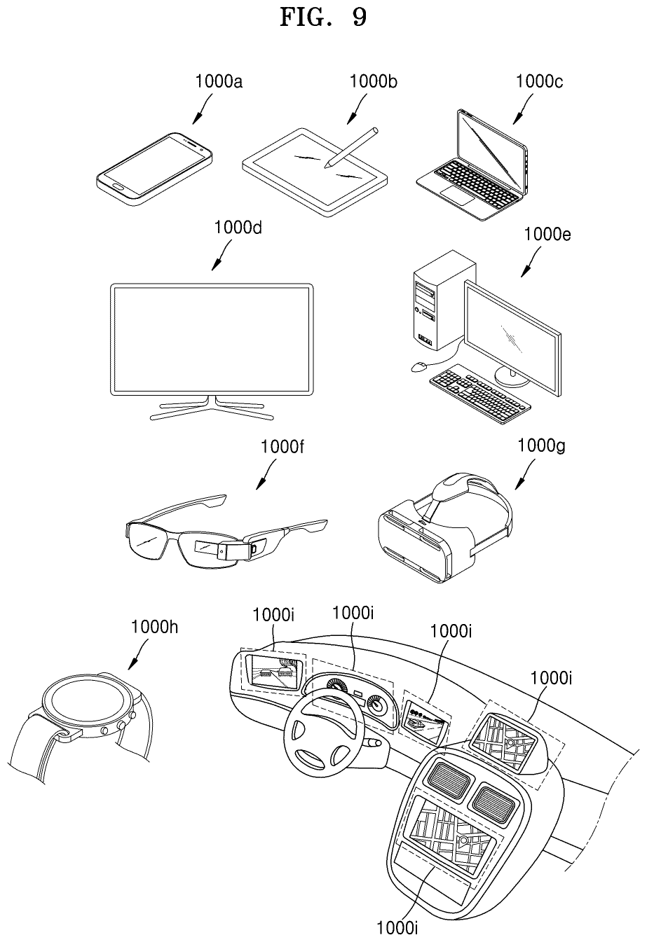

FIG. 9 is schematic diagrams of electronic apparatuses according to various embodiments.

Referring to FIG. 9, various electronic apparatuses to which display apparatuses according to embodiments are applied may include not only image display electronic apparatuses such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

According to the embodiment of the present disclosure described above, a display apparatus capable of displaying a high-quality image may be implemented. However, the scope of the present disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While the present disclosure has been described with reference to the drawings and embodiments thereof, it will be understood by those of ordinary skill in the art that various changes in form and details may be made thereto without departing from the spirit and scope of the present disclosure as set forth and defined by the following claims.

What is claimed is:

1. A display apparatus comprising:
a substrate;
a first transistor including a first semiconductor layer disposed on the substrate and a first gate electrode disposed on the first semiconductor layer, the first gate electrode including a first gate layer and a second gate layer on the first gate layer;
a storage capacitor including a first storage capacitor electrode disposed on a same layer as the first semiconductor layer and a second storage capacitor electrode disposed on a same layer as the first gate layer; and
a holding capacitor including a first holding capacitor electrode disposed on a same layer as the first semiconductor layer and a second holding capacitor electrode disposed on a same layer as the first gate layer,
wherein each of a thickness of the second storage capacitor electrode and a thickness of the second holding capacitor electrode is less than a thickness of the first gate electrode.

2. The display apparatus of claim 1, wherein each of the thickness of the second storage capacitor electrode and the thickness of the second holding capacitor electrode is less than a thickness of the second gate layer.

3. The display apparatus of claim 1, wherein each of the thickness of the second storage capacitor electrode and the thickness of the second holding capacitor electrode is equal to a thickness of the first gate layer.

4. The display apparatus of claim 1, wherein a thickness of the first gate layer is less than a thickness of the second gate layer.

5. The display apparatus of claim 1, further comprising:
a first insulating layer disposed between the first semiconductor layer and the first gate electrode; and
a second insulating layer disposed on the first insulating layer and covering the first gate electrode,
wherein the second storage capacitor electrode and the second gate layer are in contact with the second insulating layer.

6. The display apparatus of claim 1, wherein the second gate layer includes a conductive material having an etch selectivity with respect to the first gate layer.

7. The display apparatus of claim 1, further comprising a second transistor including a second semiconductor layer disposed on the second storage capacitor electrode and a second gate electrode disposed on the second semiconductor layer.

8. The display apparatus of claim 7, wherein the holding capacitor further includes a third holding capacitor electrode disposed on the second holding capacitor electrode and electrically connected to the first holding capacitor electrode.

9. The display apparatus of claim 8, wherein the third holding capacitor electrode is disposed between the second holding capacitor electrode and the second semiconductor layer.

10. The display apparatus of claim 9, wherein the holding capacitor further includes a fourth holding capacitor electrode disposed on a same layer as the second semiconductor layer and electrically connected to the second holding capacitor electrode.

11. The display apparatus of claim 8, wherein the third holding capacitor electrode is disposed on a same layer as the second semiconductor layer.

12. The display apparatus of claim 8, wherein the third holding capacitor electrode is disposed on a same layer as the second gate electrode.

13. The display apparatus of claim 8, wherein the holding capacitor further includes a fifth holding capacitor electrode disposed under the first semiconductor layer and electrically connected to the second holding capacitor electrode.

14. The display apparatus of claim 7, wherein the first semiconductor layer includes a silicon semiconductor material, and the second semiconductor layer includes an oxide semiconductor material.

15. The display apparatus of claim 1, wherein the first semiconductor layer includes an oxide semiconductor material.

16. A display apparatus comprising:
a substrate;
a first transistor including a first semiconductor layer disposed on the substrate and a first gate electrode including a first gate layer on the first semiconductor layer and a second gate layer on the first gate layer; and
a capacitor including a first capacitor electrode disposed on a same layer as the first semiconductor layer and a second capacitor electrode disposed on a same layer as the first gate layer,
wherein a thickness of the second capacitor electrode is less than a thickness of the first gate electrode.

17. The display apparatus of claim 16, wherein the thickness of the second capacitor electrode is less than a thickness of the second gate layer.

18. The display apparatus of claim 16, wherein a thickness of the first gate layer is less than a thickness of the second gate layer.

19. The display apparatus of claim 16, wherein the thickness of the second capacitor electrode is equal to a thickness of the first gate layer.

20. The display apparatus of claim 16, further comprising:
a first insulating layer disposed between the first semiconductor layer and the first gate electrode; and
a second insulating layer disposed on the first insulating layer and covering the first gate electrode,
wherein the second capacitor electrode and the second gate layer are in contact with the second insulating layer.

21. An electronic apparatus comprising a display apparatus,
wherein the display apparatus comprises:
a substrate;
a first transistor including a first semiconductor layer disposed on the substrate and a first gate electrode disposed on the first semiconductor layer, the first gate electrode including a first gate layer and a second gate layer on the first gate layer;
a storage capacitor including a first storage capacitor electrode disposed on a same layer as the first semiconductor layer and a second storage capacitor electrode disposed on a same layer as the first gate layer; and
a holding capacitor including a first holding capacitor electrode disposed on a same layer as the first semiconductor layer and a second holding capacitor electrode disposed on a same layer as the first gate layer,
wherein each of a thickness of the second storage capacitor electrode and a thickness of the second holding capacitor electrode is less than a thickness of the first gate electrode.

22. The electronic apparatus of claim 21, further comprising:
a display module;
a processor; a power module; and
a memory,
wherein the display apparatus includes one of the display module, the processor, the power module, or the memory.
